(19) United States
(12) Patent Application Publication
(10) Pub. No.: US 2024/0242005 A1
(43) Pub. Date: Jul. 18, 2024

(54) Almond Management Method and System

(71) Applicant: Valent U.S.A. LLC, San Ramon, CA (US)

(72) Inventor: Patrick Allen Clay, Fresno, CA (US)

(21) Appl. No.: 18/414,869

(22) Filed: Jan. 17, 2024

Related U.S. Application Data
(60) Provisional application No. 63/439,651, filed on Jan. 18, 2023.

(51) Int. Cl. G06F 30/20

(52) U.S. Cl. CPC G06F 30/20

(57) ABSTRACT

The present invention is related to a computer-implemented cloud-based almond management system and methods. The system comprises a plurality of user inputs and prediction models for determining application timing of [S]-trans-2-amino-4-(2-aminoethoxy)-3-butenoic acid hydrochloride (AVG-HCl).

### FIELD OF THE INVENTION

The present invention is related to a computer-implemented cloud-based almond management system and methods. The system comprises a plurality of user inputs and prediction models for determining application timing of [S]-trans-2-amino-4-(2-aminoethoxy)-3-butenoic acid hydrochloride (AVG-HCl) in almonds.

### BACKGROUND OF THE INVENTION

ReTain® is a 15% w/w solution of [S]-trans-2-Amino-4-(2-aminoethoxy)-3-butenoic acid hydrochloride also known as aminoethoxyvinylglycine hydrochloride or AVG-HCl. Almond growers apply ReTain® to their almond trees to increase nut set. Application timing of ReTain® to almond trees is suggested to occur from 10% to 100% bloom, or when 10% to 100% of the buds have bloomed. Application timing is problematic as almond grower's perception of bloom can be varied and inaccurate based on the grower's experience level, the variety of almond tree being observed and other factors.

Applying ReTain® too early or too late in the growing season may reduce its efficacy and could lead to no effect at all. Given the relatively expensive cost of the product and its application, misapplication of ReTain® will lead to financial burdens to the grower.

Thus, there is a need in the art for a system capable of determining and communicating to almond growers the proper time to apply ReTain®.

### SUMMARY OF THE INVENTION

The present invention is directed to a computerized method for determining application timing of [S]-trans-2-Amino-4-(2-aminoethoxy)-3-butenoic acid hydrochloride comprising the following steps:
collecting from a user and storing into one or more cloud-based databases one or more user observations of a site comprising one or more almond trees, the one or more user observations comprising a geographic location of the site, a user-perceived percentage of bloom for the one or more almond trees at the site, a variety of the one or more almond trees at the site and one or more images of the one or more almond trees at the site;
selecting a bloom progression model;
predicting a bloom progression rate for the one or more almond trees at the site; and
determining an application timing of [S]-trans-2-amino-4-(2-aminoethoxy)-3-butenoic acid hydrochloride.

The present invention is directed to a computer system for determining application timing of [S]-trans-2-Amino-4-(2-aminoethoxy)-3-butenoic acid hydrochloride comprising:
a memory;
one or more cloud-based databases;
a network or a communication connection; and
a processing structure coupled to the memory, the one or more cloud-based databases, and the network or the communication connection form a single computerized platform;
and wherein the processing structure is configured for:
   collecting from a user and storing into one or more cloud-based databases one or more user observations of a site comprising one or more almond trees, the one or more user observations comprising a geographic location of the site, a user-perceived percentage of bloom for the one or more almond trees at the site, a variety of the one or more almond trees at the site and one or more images of the one or more almond trees at the site;
   selecting a bloom progression model;
   predicting a bloom progression rate for the one or more almond trees at the site; and
   determining an application timing of [S]-trans-2-amino-4-(2-aminoethoxy)-3-butenoic acid hydrochloride.

### BRIEF DESCRIPTION OF THE DRAWINGS

FIG. 1. is a diagrammatic illustration of one embodiment of a method and a system disclosed herein for determining the application timing of ReTain® on almond trees.

### DETAILED DESCRIPTION OF THE INVENTION

The Applicant previously discovered that optimal application timing of ReTain® to almond trees occurs between 30% and 60% bloom. The present invention provides accurate determination of percentage of bloom of almond trees and determines and communicates to an end user the proper time to apply ReTain® to their almond trees to ensure optimal nut set. Optimum nut set provides maximum return on investment for the end user.

As used herein “user” or “end-user” refers to an individual or entity which grows or is in the business of growing and selling almonds or applies ReTain® to almond trees.

As used herein the term “site” or “field” refers to a discreet plot of land in which one or more almond trees are growing and/or living and is defined by one or more borders.

As used herein the term “ReTain®” refers to a composition containing about 15% w/w S]-trans-2-Amino-4-(2-aminoethoxy)-3-butenoic acid hydrochloride.

As used herein the term “geographic location” refers to the location of a site or field as defined by the geographic coordinate system, which uses latitude and longitude to precisely locate any point on Earth.

As used herein the term “computerized” refers to a method that is performed using one or more computers.

As used herein the term “computer” refers to any non-human device capable of storing, retrieving and processing data.

As used herein the term “application timing” refers to the time of year in which ReTain® is, will be or should be applied.

As used herein, “almond variety” or “almond tree variety” includes but is not limited to Butte, Carmel, Nonpareil, Sweet, Peerless, Green, Fritz, Sonora, Ferraduel and Molar.

As used herein, “bloom image” or “bloom images” refers to an image of an almond tree in bloom.

As used herein, the term “date range” may include one or more dates.

In one embodiment, the present invention is directed to a computerized method for determining application timing of [S]-trans-2-Amino-4-(2-aminoethoxy)-3-butenoic acid hydrochloride (“AVG-HCl”) comprising the following steps:
collecting from a user and storing into one or more cloud-based databases one or more user observations of a site comprising one or more almond trees, the one or more user observations comprising a geographic location of the site, a user-perceived percentage of bloom for the one or more almond trees at the site, a variety of the one or more almond trees at the site and one or more images of the one or more almond trees at the site;
selecting a bloom progression model;
predicting a bloom progression rate for the one or more almond trees at the site; and
determining an application timing of AVG-HCl.

The collection and storage of one or more user observations may occur manually or automatically. Manual collection may include auditory communication between the user and an individual collecting and storing the one or more user observations.

The collection and storage of one or more user observations from the user may comprise the use of a user device and/or a computer application. The user device may be a computer, including a mobile computer, including a smartphone. The user device may be running a computer application, including a mobile application designed to receive the user observations.

The collection of a geographic location of the site may occur by utilizing a global positioning system receiver and/or augmented global positioning system on the user device.

In a preferred embodiment, the computerized method of the present invention further comprises the step of providing to the user one or more bloom images.

In a preferred embodiment, one or more bloom images may be stored on the user device or on the one or more cloud-based databases. If the one or more bloom images are stored on the one or more cloud-based databases, then the one or more images may be accessed by the computer application and/or user device via network connection to the one or more cloud-based databases. In a more preferred embodiment, the one or more bloom images comprise images from each variety of almond tree. In another preferred embodiment, the one or more bloom images comprise images of almond trees with various percentages of bloom. In an even more preferred embodiment, the one or more bloom images comprise images of one or more varieties of almond trees selected from the group consisting of Butte, Carmel, Nonpareil, Sweet, Peerless, Green, Fritz, Sonora, Ferraduel and Molar. In another even more preferred embodiment, the one or more bloom images of one or more almond trees at one or more percentages of bloom selected from the group consisting of 5%, 10%, 20%, 30%, 40%, 50%, 60%, 70%, 80%, 90% and 100%. In a more preferred embodiment, the one or more bloom images of one or more almond trees may include almond trees at any percentage of bloom.

In a preferred embodiment, the computerized method of the present invention further comprises the step of communicating to the user the determined application timing of AVG-HCl.

In another preferred embodiment, the computerized method of the present invention further comprises the step of obtaining weather conditions for the geographic location of the site.

The selection of a bloom progression model may occur manually or automatically. The bloom progression model may be related only to the one or more user observations. The bloom progression model may be selected by an individual considering the one or more user observations. The bloom progression model may be selected by an individual wherein the individual modifies the one or more user observations to select the appropriate bloom progression model.

In another preferred embodiment, the selection of the bloom progression model is related to the variety of the one or more almond trees at the site.

In another preferred embodiment, the predicted bloom progression rate for the one or more almond trees at the site is related to the one or more user observations and the selected bloom progression model.

In another preferred embodiment, the predicted bloom progression rate for the one or more almond trees at the site is related to the obtained weather conditions for the geographic location of the site.

In another preferred embodiment, the determination of application timing of AVG-HCl is related to the predicted bloom progression rate for the one or more almond trees at the site.

In another preferred embodiment, each of the steps of selection of a bloom progression model, prediction of a bloom progression rate, determination of application timing of AVG-HCl, communication to the user and obtainment of weather conditions are individually automatic.

In a most preferred embodiment, the present invention is directed to a computerized method for determining application timing of [S]-trans-2-Amino-4-(2-aminoethoxy)-3-butenoic acid hydrochloride (AVG-HCl) comprising the following steps:
collecting from a user and storing into one or more cloud-based databases a plurality of user observations of a site comprising one or more almond trees, the plurality of user observations comprising a geographic location of the site, a user-perceived percentage of bloom for the one or more almond trees at the site, a variety of the one or more almond trees at the site and one or more images of the one or more almond trees at the site;
automatically selecting a bloom progression model related to the variety of the one or more almond trees at the site;
automatically predicting a bloom progression rate for the one or more almond trees at the site, wherein the predicted bloom progression is related to the plurality of user inputs, the weather conditions at the site and the selected bloom progression model;
automatically determining an application timing of AVG-HCl; and
automatically communicating the determined application timing to the user.

In another embodiment, the present invention is directed to a computer system for determining application timing of AVG-HCl comprising:
a memory;
one or more cloud-based databases;
a network or a communication connection; and
a processing structure coupled to the memory, the one or more cloud-based databases, and the network or the communication connection form a single computerized platform;
and wherein the processing structure is configured for:
collecting from a user and storing into one or more cloud-based databases one or more user observations of a site comprising one or more almond trees, the one or more user observations comprising a geographic location of the site, a user-perceived percentage of bloom for the one or more almond trees at the site, a variety of the one or more almond trees at the site and one or more images of the one or more almond trees at the site;
selecting a bloom progression model;
predicting a bloom progression rate for the one or more almond trees at the site; and
determining an application timing of AVG-HCl.

The computer system of the present invention may comprise a user device.

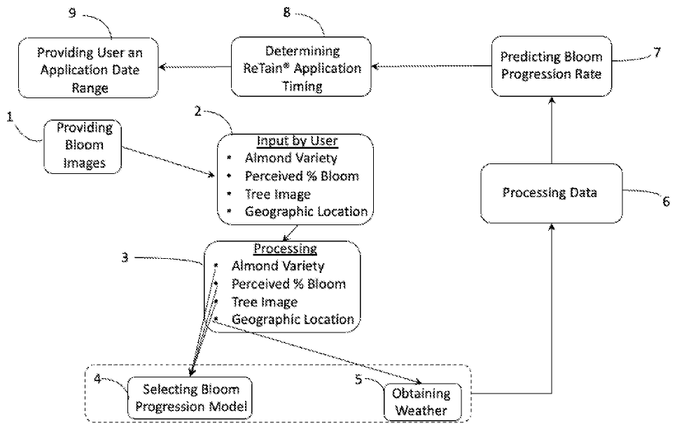

An embodiment of a computerized method of the present invention is shown in FIG. 1 and generally provides for providing a set of bloom images to the user 1, input by the user of a plurality of user observations based on the almond tree site 2, processing of the plurality of user observations 3, selecting a bloom progression model based on the user observed almond variety, the user perceived percentage bloom and the user tree image 4, obtaining weather data for the almond tree site based on the user observed geographic location 5, processing the bloom progression model and the weather data 6, predicting a bloom progression rate 7, determining application timing of ReTain® 8 to the almond tree site, and providing to the user an application date range for ReTain® to the almond tree site 9.

These representative embodiments are in no way limiting and are described solely to illustrate some aspects of the invention.

Further, the following example(s) are offered by way of illustration only and not by way of limitation.

### EXAMPLE

### Example 1—Application Timing Selection

A user desires to determine application timing of ReTain® (ReTain contains 15% w/w [S]-trans-2-Amino-4-(2-aminoethoxy)-3-butenoic acid hydrochloride (aminoethoxyvinylglycine hydrochloride; AVG-HCl) as the active ingredient; ReTain is a registered trademark of Valent BioSciences LLC) to almond trees.

The user communicates verbally to an individual a geographic location for an almond tree site for which the user desires to determine application timing of ReTain®. The individual inputs the geographic location into a cloud-based computerized system for determining application timing. The user further inputs into a user device the variety of almond tree in the field and a user-perceived percentage of bloom for one or more almond trees within the field into the computerized system. The mobile application provides one or more bloom images of each variety of almond trees at various bloom stages that may be referred to by the user when determining the user-perceived percentage of bloom. These bloom images are stored on the Cloud-based databases and may be called by the mobile application via a networked connection to the Cloud-based database or may be stored locally on the smartphone. The user uploads one or more images of one or more almond trees from the field to the computerized system.

The cloud-based computerized system stores the one or more images in the cloud. The computerized system further selects a bloom progression model based on the variety of almond tree in the field. The computerized system also obtains the future weather conditions for the field.

The cloud-based computerized system processes the user inputs to predict bloom progression for the almond tree field by utilizing at least one of the weather conditions at the geographic location of the almond tree field, the percentage bloom, and the variety of almond tree. The computerized system further determines an application timing for ReTain® to the field based on the predicted bloom progression. The computerized system communicates the application timing to the user via the user input device.

The above-described application timing selection may also be used to determine application timing to a single almond tree.

What is claimed is:

1. A computerized method for determining application timing of [S]-trans-2-Amino-4-(2-aminoethoxy)-3-butenoic acid hydrochloride comprising the following steps:
collecting from a user and storing into one or more cloud-based databases one or more user observations of a site comprising one or more almond trees, the one or more user observations comprising a geographic location of the site, a user-perceived percentage of bloom for the one or more almond trees at the site, a variety of the one or more almond trees at the site and one or more images of the one or more almond trees at the site;
selecting a bloom progression model;
predicting a bloom progression rate for the one or more almond trees at the site; and
determining an application timing of [S]-trans-2-amino-4-(2-aminoethoxy)-3-butenoic acid hydrochloride (AVG-HCl).

2. The method of claim 1, further comprising the step of communicating to the user the determined application timing of AVG-HCl.

3. The method of claim 1, further comprising the step of providing to the user one or more bloom images.

4. The method of claim 3, wherein the one or more bloom images comprise images of one or more varieties of almond trees selected from the group consisting of Butte, Carmel, Nonpareil, Sweet, Peerless, Green, Fritz, Sonora, Ferraduel and Molar.

5. The method of claim 3, wherein the one or more bloom images comprise images of one or more almond trees at one or more percentages of bloom selected from the group consisting of 5%, 10%, 20%, 30%, 40%, 50%, 60%, 70%, 80%, 90% and 100%.

6. The method of claim 1, wherein the selection of the bloom progression model is related to the variety of the one or more almond trees at the site.

7. The method of claim 1, further comprising obtaining weather conditions for the geographic location of the site.

8. The method of claim 1, wherein the predicted bloom progression rate for the one or more almond trees at the site is related to the one or more user observations and the selected bloom progression model.

9. The method of claim 8, wherein the predicted bloom progression rate is related to the selected bloom progression model.

10. The method of claim 9, wherein the predicted bloom progression rate is related to the obtained weather conditions for the geographic location of the site.

11. The method of claim 1, wherein the determination of application timing of AVG-HCl is related to the predicted bloom progression rate for the one or more almond trees at the site.

12. The method of claim 1, wherein the selection of a bloom progression model is automatic.

13. The method of claim 1, wherein the prediction of bloom progression rate is automatic.

14. The method of claim 1, wherein the determination of application timing of AVG-HCl is automatic.

15. The method of claim 2, wherein the communication to the user is automatic.

16. The method of claim 7, wherein the weather conditions are automatically obtained.

17. A computerized method for determining application timing of [S]-trans-2-Amino-4-(2-aminoethoxy)-3-butenoic acid hydrochloride comprising the following steps:
collecting from a user and storing into one or more cloud-based databases a plurality of user observations of a site comprising one or more almond trees, the plurality of user observations comprising a geographic location of the site, a user-perceived percentage of bloom for the one or more almond trees at the site, a variety of the one or more almond trees at the site and one or more images of the one or more almond trees at the site;
automatically selecting a bloom progression model related to the variety of the one or more almond trees at the site;
automatically predicting a bloom progression rate for the one or more almond trees at the site, wherein the predicted bloom progression is related to the plurality of user inputs, the weather conditions at the site and the selected bloom progression model;
automatically determining an application timing of [S]-trans-2-amino-4-(2-aminoethoxy)-3-butenoic acid hydrochloride (AVG-HCl); and
automatically communicating the determined application timing to the user.

18. A computer system for determining application timing of [S]-trans-2-Amino-4-(2-aminoethoxy)-3-butenoic acid hydrochloride comprising:
a memory;
one or more cloud-based databases;
a network or a communication connection; and
a processing structure coupled to the memory, the one or more cloud-based databases, and the network or the communication connection form a single computerized platform;
and wherein the processing structure is configured for:
collecting from a user and storing into one or more cloud-based databases one or more user observations of a site comprising one or more almond trees, the one or more user observations comprising a geographic location of the site, a user-perceived percentage of bloom for the one or more almond trees at the site, a variety of the one or more almond trees at the site and one or more images of the one or more almond trees at the site;
selecting a bloom progression model;
predicting a bloom progression rate for the one or more almond trees at the site; and
determining an application timing of [S]-trans-2-amino-4-(2-aminoethoxy)-3-butenoic acid hydrochloride (AVG-HCl).
